(19) United States
(12) Patent Application Publication
(10) Pub. No.: US 2018/0221917 A1
(43) Pub. Date: Aug. 9, 2018

(54) CAPACITIVE MICROMACHINED ULTRASONIC TRANSDUCER AND METHOD FOR MANUFACTURING THE SAME

(71) Applicant: CANON KABUSHIKI KAISHA, Tokyo (JP)

(72) Inventors: Ayako Maruyama, Sagamihara-shi (JP); Yutaka Setomoto, Sagamihara-shi (JP)

(21) Appl. No.: 15/890,033

(22) Filed: Feb. 6, 2018

(30) Foreign Application Priority Data
Feb. 9, 2017 (JP) 2017-022466

(51) Int. Cl. B06B 1/02; G01N 29/24; B81B 3/00; G01H 11/06

(52) U.S. Cl. CPC B06B 1/0292; B06B 1/0207; B06B 2201/51; B81B 3/0021; G01H 11/06; G01N 29/2406

(57) ABSTRACT

A capacitive micromachined ultrasonic transducer includes an element. The element includes a plurality of cells. First electrodes in the plurality of cells are electrically connected together to form a first common electrode, and second electrodes in the plurality of cells are electrically connected together to form a second common electrode. The first common electrode and the second common electrode are opposed to each other only in an area with the gap therebetween. An area of the element with the first common electrode is wider than an area of the element without the first common electrode.

### BACKGROUND

### Field

The present disclosure relates to a capacitive micromachined ultrasonic transducer and a method for manufacturing the same.

### Description of the Related Art

Conventionally, micromechanical members manufactured by micromachining techniques have been capable of micrometer-order processing, and have been used to implement various micro-functional elements. Capacitive micromachined ultrasonic transducers using this technology have been studied as a replacement of piezoelectric elements mounted in conventional ultrasonic transducers. The capacitive micromachined ultrasonic transducer can transmit and receive acoustic waves (ultrasonic waves) using vibration of a vibrating membrane. The capacitive micromachined ultrasonic transducer has a cell in which a vibrating membrane including one of a pair of electrodes formed with a gap therebetween is supported in a manner capable of vibrating. Hereinafter, the capacitive micromachined ultrasonic transducer may be abbreviated as CMUT. An ultrasonic diagnosis apparatus transmits an acoustic wave from an ultrasonic transducer to a subject, receives a reflection signal from the subject by the ultrasonic transducer, and generates an ultrasound image based on the received signal. An ultrasonic probe included in the ultrasonic diagnosis apparatus desirably transmits a large ultrasonic wave and receives a small echo signal reflected from the subject.

PCT Japanese Translation Patent Publication No. 2003-500955 discloses a configuration in which a CMUT is used as an ultrasonic converter to reduce parasitic capacity generated between upper and lower electrodes in the CMUT. According to PCT Japanese Translation Patent Publication No. 2003-500955, a pair of electrodes is patterned in an area without a vibrating membrane, and the electrodes are not opposed to each other in an area without a cavity between the electrodes to reduce parasitic capacitance.

However, patterning the electrodes decreases the electrode area and increases the wiring resistance, thereby deteriorating the characteristics of transmitting and receiving ultrasonic waves.

### SUMMARY

A capacitive micromachined ultrasonic transducer according to the present disclosure is a capacitive micromachined ultrasonic transducer including an element. The element includes a plurality of cells. Each of the cells includes a substrate, a first electrode provided on the substrate, and a vibrating membrane that has a second electrode opposed to the first electrode with a gap between the first and second electrodes. The first electrodes in the plurality of cells are electrically connected together to form a first common electrode. The second electrodes in the plurality of cells are electrically connected together to form a second common electrode. The first common electrode and the second common electrode are opposed to each other only in an area with the gap therebetween. An area of the element with the first common electrode is wider than an area of the element without the first common electrode.

A method for manufacturing a capacitive micromachined ultrasonic transducer including an element with a plurality of cell structures includes: forming a first electrode on a substrate; forming a plurality of sacrifice layer areas on the first electrode such that the individual cell structures have independent gaps; forming a second electrode on the sacrifice layer areas; removing the sacrifice layer areas and forming the independent gaps in the individual cell structures. The first electrode is formed such that the first electrode and the second electrode are opposed to each other only in an area with the gap therebetween.

Further features will become apparent from the following description of exemplary embodiments (with reference to the attached drawings).

### BRIEF DESCRIPTION OF THE DRAWINGS

FIG. 1 is a top view of a CMUT according to an embodiment.

FIG. 2 is an enlarged partial view of FIG. 1.

FIG. 3 is a cross-sectional view of FIG. 2 taken along line A-B for describing the CMUT.

FIG. 4 is a cross-sectional view of FIG. 2 taken along line C-D for describing the CMUT.

FIG. 5 is a cross-sectional diagram of the CMUT for describing driving of the CMUT.

FIG. 6 is a top view of the CMUT after formation of a first electrode for describing the CMUT.

FIG. 7 is a diagram illustrating an example of a driving device for driving the CMUT.

FIG. 8 is a diagram illustrating an example of a transmission-reception circuit for driving the CMUT.

FIG. 9 is a diagram illustrating an example of an ultrasonic probe for describing the CMUT.

FIG. 10 is a cross-sectional view of FIG. 1 taken along line C-D without removal of a first electrode.

FIG. 11 is a diagram illustrating an example of a transimpedance current-voltage amplifier circuit.

FIG. 12 is a top view of FIG. 2 after formation of the first electrode.

FIGS. 13A-13F are cross-sectional views of FIG. 1 taken along line E-F for describing a method for manufacturing the CMUT.

FIG. 14 is a top view of a CMUT according to Example 1.

FIGS. 15A-15C are cross-sectional views of FIG. 1 taken along line E-F for describing a method for manufacturing the CMUT according to Example 1.

FIG. 16 is a graph illustrating changes in S/N according to Example 1.

FIG. 17 is a graph illustrating variation changes in S/N according to Example 1.

FIG. 18 is a diagram of a transmission circuit according to Example 2.

FIG. 19 is a graph illustrating the amplitude of a transmission driving voltage on which electric crosstalk is superimposed according to Example 2.

FIG. 20 is a graph illustrating the amplitude of a transmission driving voltage on which electric crosstalk is superimposed according to Example 2.

FIG. 21 is a graph illustrating the amplitude of a transmission driving voltage on which electric crosstalk is superimposed according to Example 2.

FIG. 22 is a graph illustrating the ratio of sound pressure at 8 MHz at a focal position according to Example 2.

FIG. 23 is a graph illustrating the distribution of sound pressure at 8 MHz at a focal position according to Example 2.

FIG. 24 is a graph illustrating azimuth resolution at 8 MHz at a focal position according to Example 2.

### DESCRIPTION OF THE EMBODIMENTS

### (Capacitive Micromachined Ultrasonic Transducer)

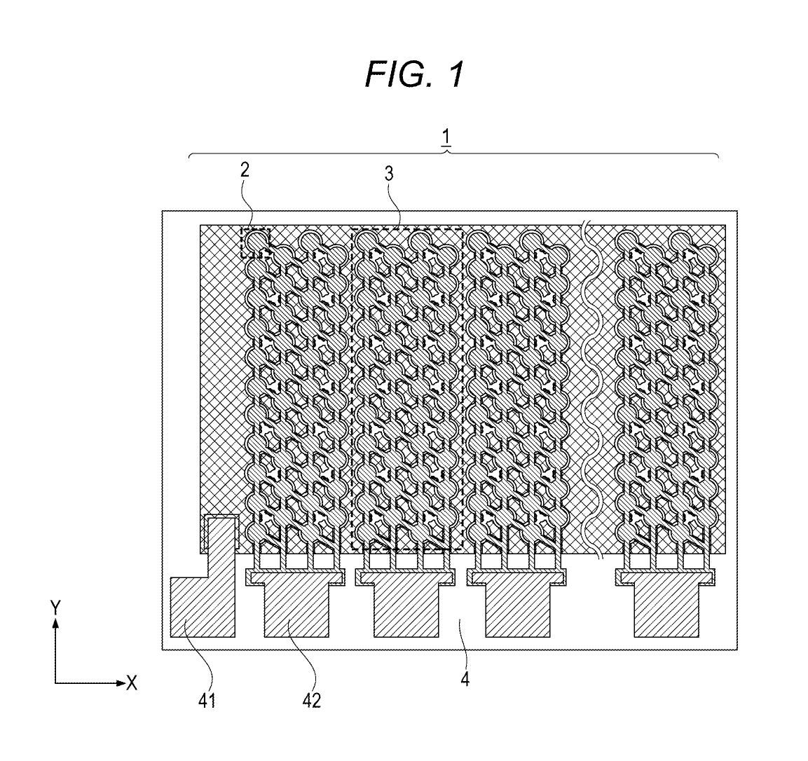

A capacitive micromachined ultrasonic transducer (CMUT) according to an embodiment of the present disclosure will be described with reference to FIGS. 1 to 6.

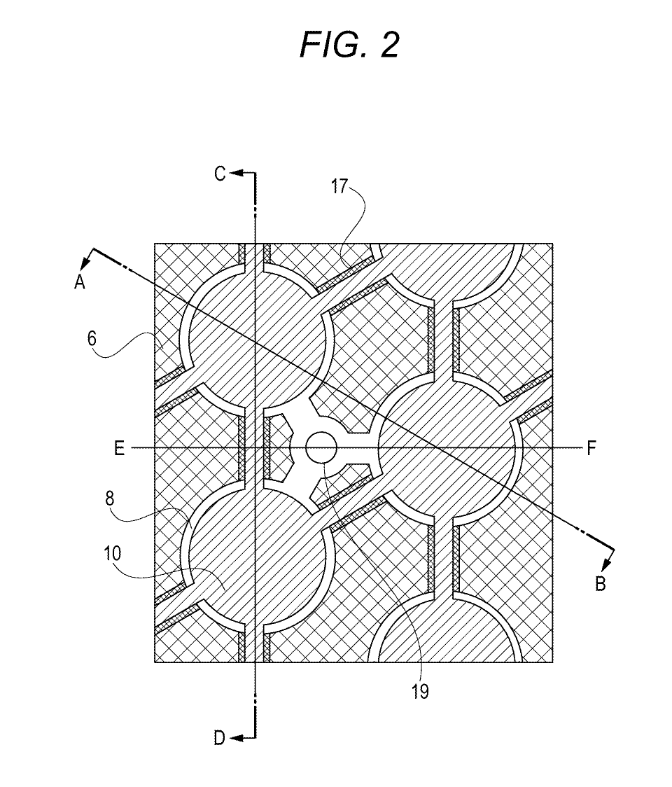

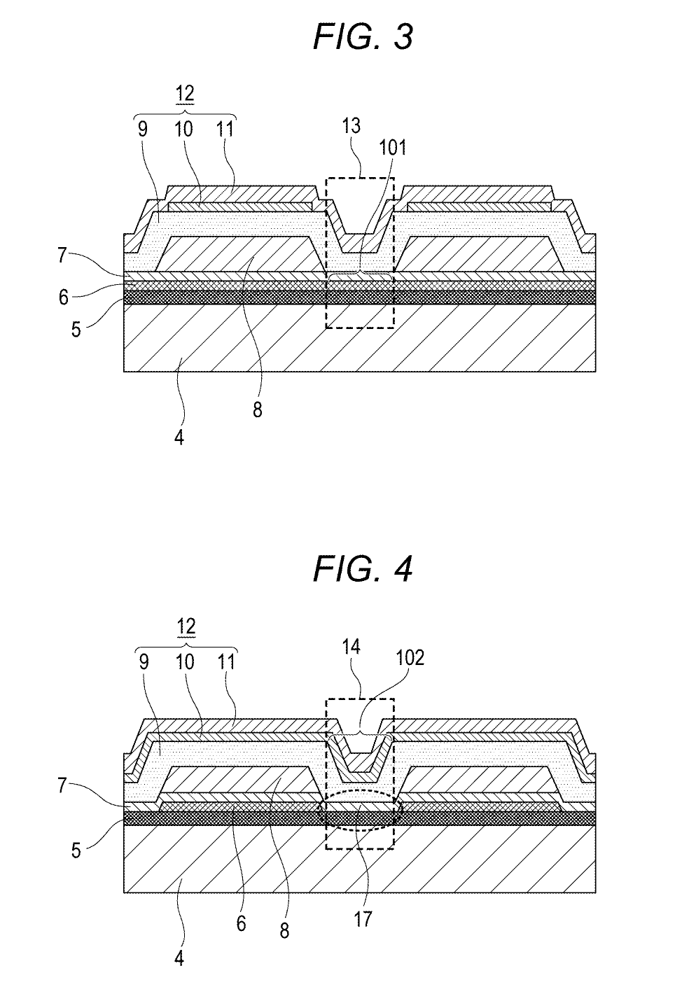

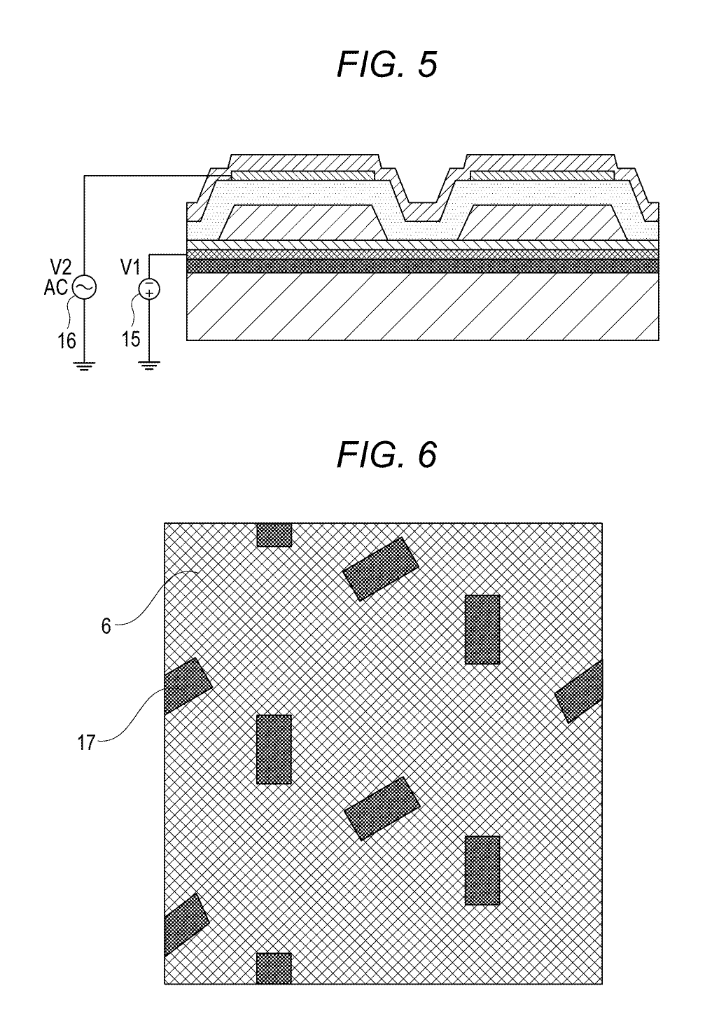

FIG. 1 is a top view of the CMUT according to the embodiment of the present disclosure, and FIG. 2 is an enlarged partial view of FIG. 1. FIG. 3 is a cross-sectional view of FIG. 2 taken along line A-B, and FIG. 4 is a cross-sectional view of FIG. 2 taken along line C-D. FIG. 4 is a cross-sectional view for describing driving of the CMUT according to the embodiment. FIG. 5 is a diagram illustrating a voltage applying unit for driving the CMUT. FIG. 6 is a top view of FIG. 1 after formation of a first electrode. The top view of FIG. 6 does not illustrate a second insulation film 7 and a sealing film 11.

In these diagrams, reference sign 1 represents a capacitive micromachined ultrasonic transducer (CMUT), reference sign 2 represents a cell, reference sign 3 represents an element including a plurality of cells 2. Each of the cells 2 has a substrate 4, a first insulation film 5, a first electrode 6, the second insulation film 7, a gap 8, a third insulation film 9, a second electrode 10, the sealing film (fifth insulation film) 11. In the embodiment, a vibrating membrane 12 has the third insulation film 9, the second electrode 10, and the sealing film 11. Reference signs 13, 14, and 18 represent vibrating membrane support members. In addition, reference sign 15 represents a first voltage applying unit, 16 a second voltage applying unit, 17 a portion from which the first electrode is removed, 19 an etching hole, 41 a first electrode pad, and 42 a second electrode pad. Only either of the voltage applying units may be provided. The area provided between the substrate and the vibrating membrane support members to connect electrically the first electrodes included in the plurality of cells may also be called first connection portion. In addition, the area provided on the vibrating membrane support members to connect electrically the second electrodes included in the plurality of cells may also be called second connection portion.

As illustrated in FIGS. 1 to 6, the capacitive micromachined ultrasonic transducer 1 according to the embodiment includes the element 3. The element 3 includes a plurality of cells 2. The element 3 here refers to a cell group as a unit of transmitting and receiving ultrasonic signals. That is, the ultrasonic signals received and transmitted by the plurality of cells 2 included in one element 3 are treated as one. The capacitive micromachined ultrasonic transducer 1 has a plurality of elements 3. Each of the elements 3 can be configured to perform at least reception or transmission of ultrasonic waves.

Each of the cells 2 includes the substrate 4, the first electrode 6 provided on the substrate 4, the vibrating membrane 12 including the second electrode 10 opposed to the first electrode 6 with the gap 8 between the second electrode 10 and the first electrode 6.

The first electrodes in the plurality of cells 2 are electrically connected to form a first common electrode (the whole area represented with reference sign 6). The second electrodes in the plurality of cells 2 are electrically connected to form a second common electrode (the whole area represented with reference sign 10).

As illustrated in FIGS. 3 and 4, the first common electrode 6 and the second common electrode 10 are opposed to each other only in the area with the gap 8 therebetween. This arrangement can reduce parasitic capacitance.

As illustrated in FIG. 1, in the element 3, the area with the first common electrode 6 is wider than the area 17 without the first common electrode. That is, the first common electrode 6 is formed in the area where the first electrode 6 and the second electrode 10 are not opposed to each other and the parasitic capacitance is unlikely to occur, thereby increasing the electrode area and decreasing the wiring resistance. For example, the resistance of the first common electrode and the second common electrode can be kept at 1Ω or less.

The area of the second electrode 10 not opposed to the first electrode 6 can be provided at least on the vibrating membrane support member 14.

The capacitive micromachined ultrasonic transducer according to the embodiment will be described below in more detail. The CMUT 1 is formed from a plurality of elements 3 having the cells 2 in which the first electrode 6 formed on the supporting substrate 4 and the vibrating membrane 12 including the second electrode 10 opposed to the first electrode 6 with the gap 8 therebetween are supported in a manner capable of vibrating. The capacitive micromachined ultrasonic transducer 1 has portion 17 from which the first electrode is removed.

FIG. 1 illustrates only four elements but the number of the elements is arbitrary. Each of the elements 3 is formed from 42 cells 2 but the number of the cells is arbitrary. The cells may be arranged in a grid pattern, a hound's-tooth pattern, or any other pattern. The general outer shape of the element 3 may be a rectangle as illustrated in FIG. 2, a regular square, or a hexagon.

As illustrated in FIGS. 1, 3, and 4, each of the cells 2 has the substrate 4, the first insulation film 5 formed on the substrate 4, the first electrode 6 formed on the first insulation film 5, and the second insulation film 7 formed on the first electrode 6. Each of the cells 2 also has the third insulation film 9, the second electrode 10, and the sealing film 11 constituting the vibrating membrane 12, and has the vibrating membrane support member 13 supporting the vibrating membrane 12 and the gap 8. The gap 8 is formed by etching a sacrifice layer via the etching hole 19 as described later. The vibrating membrane support member 13 may be in the state 13 that includes the second electrode 10 for wire leading or in the state 14 that does not include the second electrode 10. In the case where the substrate 4 is an insulating substrate such as a glass substrate, the first insulation film 5 may not be provided. The second insulation film 7 is provided for the purposes of improving the cell resistance to pressure and preventing the charging of the insulation film, but may not be provided if it is unnecessary. The sealing film 11 is provided for the purpose of controlling the deformation of the vibrating membrane 12 and sealing the gap 8, but may not be provided if it is unnecessary. The shape of the gap 8 as seen from the top is a circle and the shape of the vibrating portion is a circle but these shapes may be a regular square or a rectangle.

As illustrated in FIG. 5, the capacitive micromachined ultrasonic transducer has the voltage applying unit 15 that applies a voltage between the first electrode 6 and the second electrode 10 in the cell 2 and the voltage applying unit 16 that applies a transmission voltage to the second electrode.

The capacitive micromachined ultrasonic transducer of the present disclosure can apply a bias voltage by the first voltage applying unit 15 to the first electrode 6. When the bias voltage is applied to the first electrode 6, a potential difference occurs between the first electrode 6 and the second electrode 10. The potential difference causes the vibrating membrane 12 to displace until the restoration force and electrostatic attractive force of the vibrating membrane are matched. When an ultrasonic wave reaches the vibrating membrane 12 in this state, the vibrating membrane 12 vibrates to change the electrostatic capacity between the first electrode 6 and the second electrode 10, thereby to flow an electric current into the second electrode 10. Taking this current via the second electrode pad 42 led from the second electrode 10 makes it possible to take the ultrasonic wave as an electric signal.

An ultrasonic wave can be transmitted by the first voltage applying unit 15 applying the bias voltage to the first electrode 6 and the second voltage applying unit 16 applying a transmission driving voltage to the second electrode 10. The transmission driving voltage may have any waveform as far as it allows transmission of a desired ultrasonic wave. Any desired waveform such as unipolar pulse, bipolar pulse, burst waveform, or continuous waveform can be used.

As illustrated in FIG. 4, the embodiment is characterized by removing the first electrode 6 opposed to the second electrode 10 from the area without the gap 8. In addition, as illustrated in FIGS. 1 and 2, the first electrode 6 covers almost the entire element 3 to decrease the wiring resistance of the first electrode 6. The size of the portion 17 from which the first electrode 6 is removed is almost identical to the size of the second electrode 10 as illustrated in FIG. 2. The almost identical size is preferably the size allowing for the alignment accuracy of an exposure device used at the manufacture of the first electrode 6 and the second electrode 10 and the patterning accuracy at the time of manufacture as described later in detail in relation to a method for manufacturing the capacitive micromachined ultrasonic transducer 1. In addition, the portion 17 is preferably sized such that the parasitic capacitance described later takes a desired numeric value. FIG. 6 is a top view of the CMUT after formation of the first electrode 6. The first electrode 6 opposed to the second electrode 10 in the area without the gap 8 is removed. In the embodiment, the first electrode 6 covers the almost whole element 3 and the first electrode 6 is partially removed. Alternatively, the second electrode 10 may cover each of the almost whole elements 3. In this case, the second electrode 10 is separated between the elements and is partially removed. The first electrode 6 may be patterned as the second electrode 10 illustrated in FIG. 1 without being separated between the elements 3.

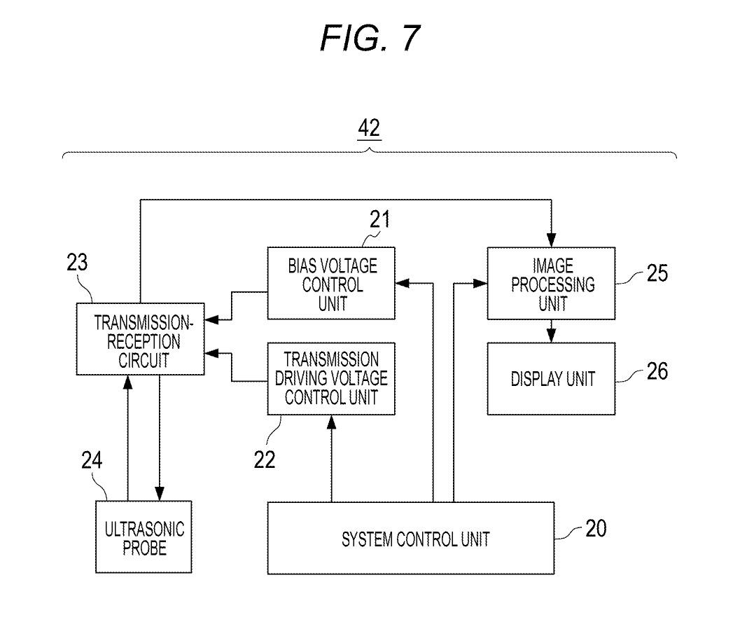

FIG. 7 illustrates an example of a driving device. A driving device 42 is formed from a system control unit 20, a bias voltage control unit 21, a transmission driving voltage control unit 22, a transmission-reception circuit 23, an ultrasonic probe 24, an image processing unit 25, and a display unit 26. The ultrasonic probe 24 is formed from the capacitive micromachined ultrasonic transducer 1 that transmits an ultrasonic wave to a subject and receives the ultrasonic wave reflected from the subject. The transmission-reception circuit 23 is a circuit that supplies an externally supplied bias voltage and a transmission driving voltage to the ultrasonic probe 24, and processes an ultrasonic wave received by the ultrasonic probe 24 and outputs the same to the image processing unit 25. The bias voltage control unit 21 supplies the bias voltage to the transmission-reception circuit 23 to supply the same to the ultrasonic probe 24. The bias voltage control unit 21 is formed from a power source and a switch not illustrated, and supplies the bias voltage to the transmission-reception circuit 23 at a time point specified by the system control unit 20. The transmission driving voltage control unit 22 supplies the transmission driving voltage to the transmission-reception circuit 23 to supply the same to the ultrasonic probe 24. The transmission driving voltage control unit 22 supplies the waveform by which to obtain desired frequency characteristics and strength of a transmission sound pressure to the transmission-reception circuit 23 at a time point specified by the system control unit 20. The image processing unit 25 performs image conversion using a signal output from the transmission-reception circuit 23 (for example, B-mode image, M-mode image, or the like), and outputs the image signal to the display unit 26. The display unit 26 is a display device that displays the image signal output from the image processing unit 25. The display unit 26 may be separated from the driving device 42. The system control unit 20 is a circuit that controls the bias voltage control unit 21, the transmission driving voltage control unit 22, the image processing unit 25, and others.

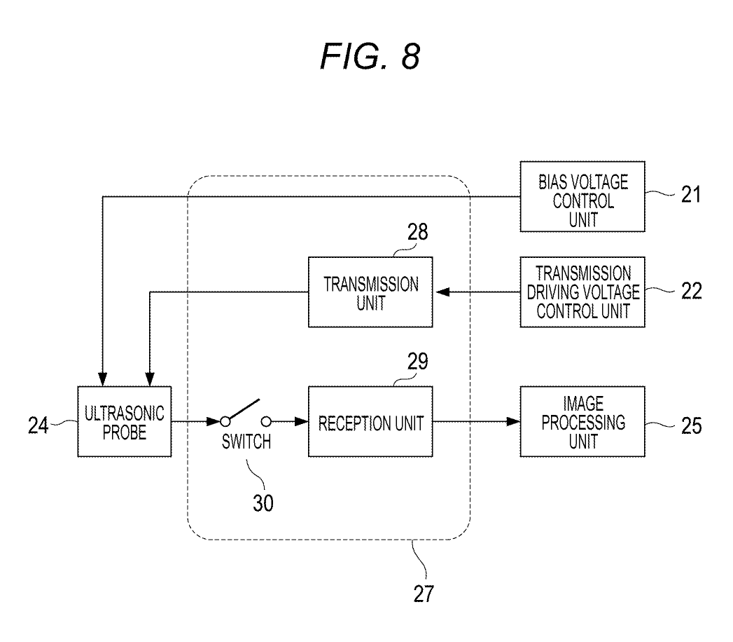

FIG. 8 illustrates an example of a transmission-reception circuit 27. The transmission-reception circuit 27 is formed from a transmission unit 28, a reception unit 29, and a switch 30. At the time of transmission driving, the transmission-reception circuit 27 applies the bias voltage from the bias voltage control unit 21 to the ultrasonic probe 24 according to the transmission bias voltage instructed by the system control unit 20 illustrated in FIG. 7. Similarly, the transmission-reception circuit 27 applies the voltage from the transmission driving voltage control unit 22 to the ultrasonic probe 24 via the transmission unit 28 according to the transmission voltage instructed by the system control unit 20. When the transmission driving voltage is applied, the switch 30 is opened so that no signal flows to the reception unit 29. When no transmission driving voltage is applied, the switch 30 is closed and the reception is possible. The switch 30 is formed from a diode or the like not illustrated and plays the role of a protection circuit to prevent the breakage of the reception unit 29. The ultrasonic probe 24 transmits an ultrasonic wave and receives the ultrasonic wave reflected and returned from the subject. At the time of reception, the transmission-reception circuit 27 applies the bias voltage from the bias voltage control unit 21 to the ultrasonic probe 24 according to the reception bias voltage instructed by the system control unit 20 illustrated in FIG. 7. The switch 30 is closed and the reception signal is amplified by the reception unit 29 and sent to the image processing unit 25.

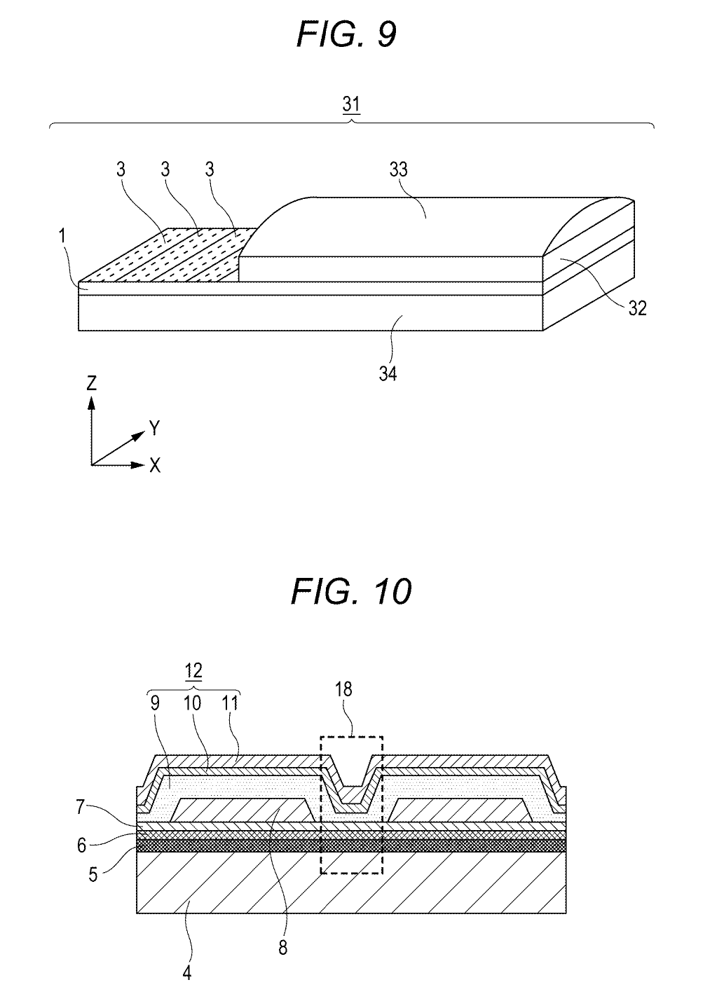

FIG. 9 is a perspective view of an example of an ultrasonic probe 31. The ultrasonic probe 31 is formed from the capacitive micromachined ultrasonic transducer 1, an acoustic matching layer 32, an acoustic lens 33, and a circuit substrate 34. The capacitive micromachined ultrasonic transducer 1 illustrated in FIG. 9 has a large number of elements 3 aligned in an X direction in a one-dimensional array as illustrated in FIG. 9. FIG. 9 illustrates the one-dimensional array, but the elements 3 may be aligned in a two-dimensional array or any other shape such as a convex pattern. The capacitive micromachined ultrasonic transducer 1 is mounted on the circuit substrate 34 and electrically connected to the circuit substrate 34. The circuit substrate 34 may be a substrate integrated with the transmission-reception circuit 27 illustrated in FIG. 8 or the capacitive micromachined ultrasonic transducer 1 may be connected to the transmission-reception circuit 27 as illustrated in FIG. 8 via the circuit substrate 34. The capacitive micromachined ultrasonic transducer 1 has the acoustic matching layer 32 on the surface side from which an ultrasonic wave is transmitted to match the acoustic impedance to the subject. The acoustic matching layer 32 may be provided as a protection film to prevent a leak of electrical current to the subject. The acoustic lens 33 is disposed via the acoustic matching layer 32. The acoustic lens 33 preferably allows matching of the acoustic impedance between the subject and the acoustic matching layer 32. Providing the acoustic lens 33 with a curvature in a Y direction as illustrated in FIG. 9 makes it possible to narrow the ultrasonic wave spreading in the Y direction at the focal position of the acoustic lens. The ultrasonic wave spreading in the X direction cannot be narrowed as it is, but performing the transmission driving by beam forming with differences in timing for transmitting the ultrasonic wave for each of the elements 3 makes it possible to narrow the ultrasonic wave at the focal position. The acoustic lens 33 is preferably shaped in such a manner as to obtain the desired distribution characteristics of ultrasonic wave. Depending on the type of the subject used, the types and shapes of the acoustic matching layer 32 and the acoustic lens 33 may be selected or the acoustic matching layer 32 and the acoustic lens 33 may not be provided. The bias voltage and the transmission driving voltage to be supplied to the ultrasonic probe 31 and the reception signal of the ultrasonic wave reflected from the subject are transmitted to the transmission-reception circuit 27 or the image processing unit 25 via a cable not illustrated.

Next, the reception characteristics of the general capacitive micromachined ultrasonic transducer 1 will be described. FIG. 10 is a cross-sectional view of FIG. 1 taken along line C-D without removal of the first electrode 6. First, the capacity of the capacitive micromachined ultrasonic transducer 1 will be described with reference to FIG. 10. FIG. 10 illustrates the substrate 4, the first insulation film 5, the first electrode 6, the second insulation film 7, the gap 8, the third insulation film 9, the second electrode 10, the sealing film 11, the vibrating membrane 12, and the vibrating membrane support member 18. Referring to FIG. 10, an active capacity Ca is generated at a portion where the first electrode 6 and the second electrode 10 are opposed to each other with the gap 8 therebetween, and a parasitic capacity Cp is generated at the other portion. The parasitic capacity may be generated at the vibrating membrane support member 18 without the gap 8, or due to the electric connection with the transmission-reception circuit or the wire routing in the substrate of the transmission-reception circuit. The reception performance and capacity of the capacitive micromachined ultrasonic transducer 1 are in such a relationship as expressed in Equation 1.

S/N∝Ca/(Ca+Cp) (Equation 1)

S represents the peak sensitivity in the reception characteristics and N integrated noise in the transmission-reception circuit. Ca represents the active capacity in the area where the vibrating membrane 12 vibrates, and Cp the parasitic capacity. The reception S/N of reception decreases at the high ratio of the parasitic capacity to the active capacity. Accordingly, the ratio of the parasitic capacity to the active capacity is preferably reduced. Employing the configuration according to the embodiment illustrated in FIG. 4 makes it possible to set the capacity of the portion 17 from which the first electrode 6 is removed to almost zero. This reduces the ratio of the parasitic capacity to the active capacity.

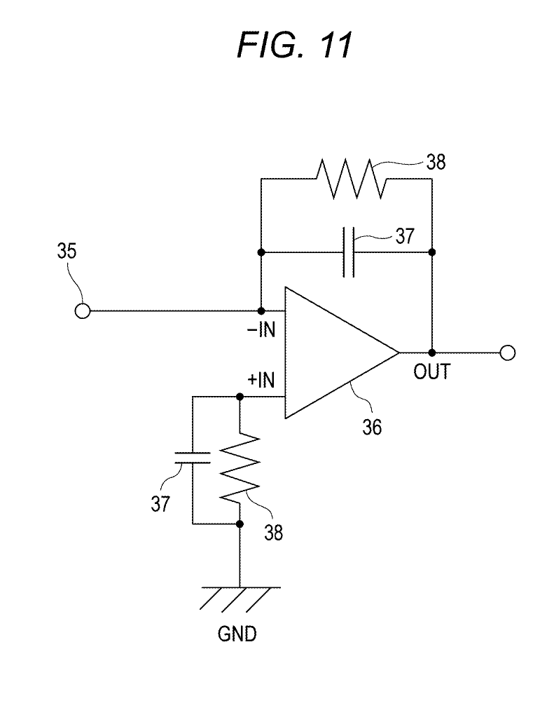

The reception unit 29 of the transmission-reception circuit 27 is generally a transimpedance-type current/voltage amplifier circuit. FIG. 11 illustrates an example of a circuit diagram of the reception unit. Referring FIG. 11, reference numeral 35 represents a capacity, 36 an operation amplifier, 37 a feedback capacity, and 38 a feedback resister. The characteristic of a circuit gain of the reception unit illustrated in FIG. 11 is expressed by Equation 2, and the cutoff frequency is expressed by Equation 3.

G=Rf/(1+j×w×Rf×Cf) (Equation 2)

f≠1/(2×π×Rf×Cf) (Equation 3)

G represents the gain, Rf the feedback resister 38, Cf the feedback capacity 37, ω the angular frequency of the input current, and f the cutoff frequency. In addition, Equation 4 needs to be satisfied for stable driving of the circuit of the reception unit illustrated in FIG. 11.

Cf≥((Cin)/(π×GBW×Rf))̂0.5=((Ca+Cp)/(π×GBW×Rf))̂0.5 (Equation 4)

GBW represents the gain bandwidth of the operation amplifier, Cin the capacity 35 parasitic on the inversion input terminal (−IN) of the operation amplifier 36, which is equal to Ca+Cp. When Cin is large, the negative feedback circuit becomes unstable and the circuit itself of the reception unit oscillates and cannot perform current-voltage conversion. Accordingly, it is necessary to select the optimum values of GBW, Rf, and Cf with respect to the value of Cin.

Further, Equations 3 and 4 define the relationship described in Equation 5.

f≠(n×GBW×Rf)̂0.5/(2×π×Rf×(Ca+Cp)̂0.5) (Equation 5)

As is seen from Equation 4, when the parasitic capacity Cp increases, the feedback capacity Cf needs to be increased for stable driving of the circuit of the reception unit. As is seen from Equation 3, when the feedback capacity Cf becomes large, the feedback resistance Rf needs to be decreased to obtain the desired cutoff frequency. As is seen from Equation 2, when the feedback resistance Rf becomes low, the circuit gain of the reception unit decreases. When the circuit gain of the reception unit decreases, the reception performance of the capacitive micromachined ultrasonic transducer 1 becomes deteriorated. In addition, as is seen from Equation 5, when the parasitic capacity increases, the cutoff frequency of the detection circuit becomes lower, the reception characteristics of the capacitive micromachined ultrasonic transducer 1 on the high-frequency side become deteriorated to narrow the reception band.

From the foregoing matter, it is preferred to reduce the ratio of the parasitic capacity to the active capacity. Employing the configuration according to the embodiment illustrated in FIG. 4 makes it possible to set the capacity of the portion 17 from which the first electrode 6 is removed to almost zero. This makes it possible to reduce the ratio of the parasitic capacity to the active capacity and improve the reception performance and reception characteristics of the capacitive micromachined ultrasonic transducer 1.

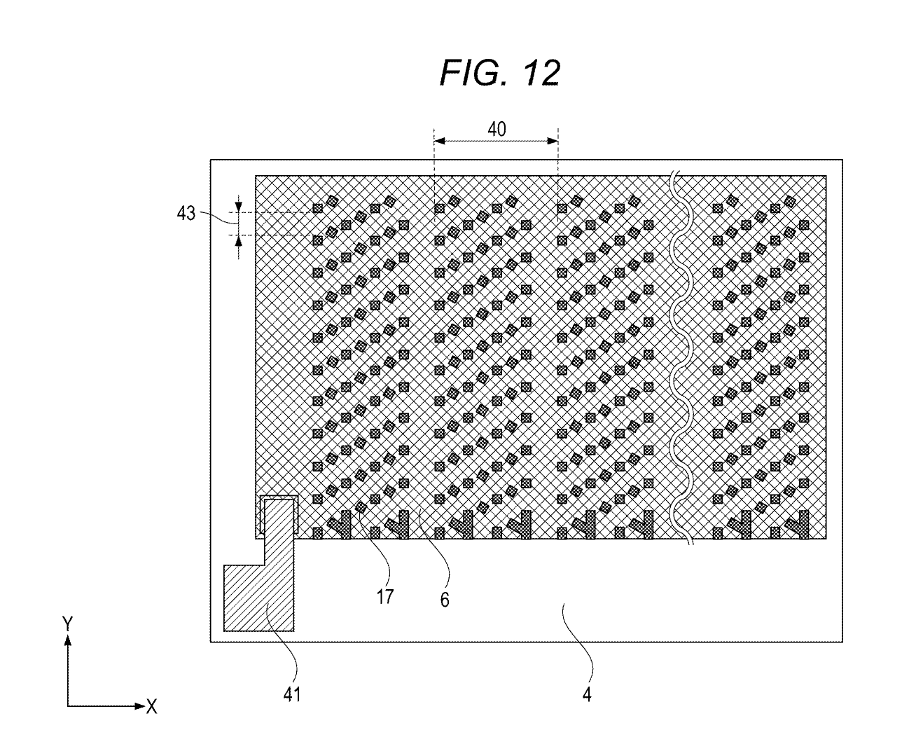

Next, the transmission characteristics of the general capacitive micromachined ultrasonic transducer will be described. FIG. 12 is a top view of FIG. 2 after formation of the first electrode. FIG. 12 illustrates the substrate 4, the first electrode 6, the portion 17 from which the first electrode is removed, an element pitch 40, the first electrode pad 41, width 43 of one stage of the first electrode.

The characteristics of sound pressure transmitted from the capacitive micromachined ultrasonic transducer 1 is determined by the product of the vibrating membrane 12 and the characteristics of the transmission driving voltage. To obtain the higher transmission sound voltage, the gap 8 is increased and a higher voltage is applied to the vibrating membrane 12 that would vibrate more greatly.

Descriptions will be given as to the ultrasonic probe 31 as illustrated in FIG. 9, for example, in which 192 elements 3 are arranged in a one-dimensional array and the transmission driving voltage will be applied to the 97th element 3 from the end. First, the bias voltage is applied to the first electrode 6 of the capacitive micromachined ultrasonic transducer 1. When the first electrode 6 is common among all the elements 3 as illustrated in FIG. 2, applying the bias voltage to the first electrode pad 41 makes it possible to apply the bias voltage to all the elements 3. Next, the transmission driving voltage is applied to the second electrode 10 of the 97th element 3 from the end so that the vibrating membrane 12 vibrates and transmits the sound pressure. At that time, the elements 3 other than the 97th one also transmit the sound pressure due to electric crosstalk. The impedance of the capacitive micromachined ultrasonic transducer seen from the 97th element 3 to which the transmission voltage is applied varies depending on the positions of the elements 3. Accordingly, when the transmission driving voltage is applied to the second electrode 10, the bias voltage fluctuates depending on the resistance of the element pitch 40 in the first electrode 6. Since the bias voltage is common among all the elements 3, the potential difference between the first electrode 6 and the second electrode 10 changes in all the elements 3 to which no transmission voltage is applied, and the vibrating membrane 12 vibrates and transmits the sound pressure. When the elements 3 without application of the transmission driving voltage transmit the sound pressure due to electric crosstalk, the desired transmission sound pressure characteristics cannot be obtained. Accordingly, the electric crosstalk is preferably small. When the resistance of the element pitch 40 in the first electrode 6 is higher, the electric crosstalk becomes large. Therefore, the resistance of the element pitch 40 in the first electrode 6 is preferably lower.

In addition, when beam forming driving is performed by the ultrasonic probe 31 as illustrated in FIG. 9, the transmission driving voltage is applied to the elements 3 with phase differences to narrow the ultrasonic wave at the desired position in the X direction. At that time, electric crosstalk occurs at the elements 3. The electric crosstalk is superimposed on the transmission driving voltage from the transmission driving voltage control unit 22 for the beam forming driving. Since the vibrating membrane 12 vibrates due to the transmission driving voltage on which the electric crosstalk is superimposed, the displacement of the vibrating membrane 12 is larger than estimated, and the vibrating membrane 12 may contact the second insulation film 7. When the vibrating membrane 12 contacts the second insulation film 7, the vibrating membrane 12 is electrically charged to cause variations in the bias voltage and the transmission driving voltage, and the vibrating membrane 12 has variations in vibration characteristics. This leads to a decrease in performance of the capacitive micromachined ultrasonic transducer 1. Accordingly, it is necessary to apply the transmission driving voltage from the transmission driving voltage control unit 22 to the second electrode 10 allowing for the electric crosstalk such that the vibrating membrane 12 does not contact the second insulation film 7 due to the transmission driving voltage on which the electric crosstalk is superimposed. The electric crosstalk becomes larger with the increasing resistance of the element pitch 40 in the first electrode 6, the transmission driving voltage to be applied from the transmission driving voltage control unit 22 to the elements 3 needs to be lowered. Thus, the transmission driving voltage applicable to the elements 3 becomes lower and the transmission sound pressure is reduced. Therefore, the resistance of the element pitch 40 in the first electrode 6 is preferably lower. This structure makes it possible to reduce the resistance of the element pitch 40 in the first electrode 6. Referring to FIG. 12, reference sign 43 represents the width of one stage of the first electrode (a method for manufacturing the capacitive micromachined ultrasonic transducer).

First, the outline of a method for manufacturing a capacitive micromachined ultrasonic transducer according to the embodiment will be described.

The method for manufacturing a capacitive micromachined ultrasonic transducer according to the embodiment is a method for manufacturing a capacitive micromachined ultrasonic transducer including at least the following steps:

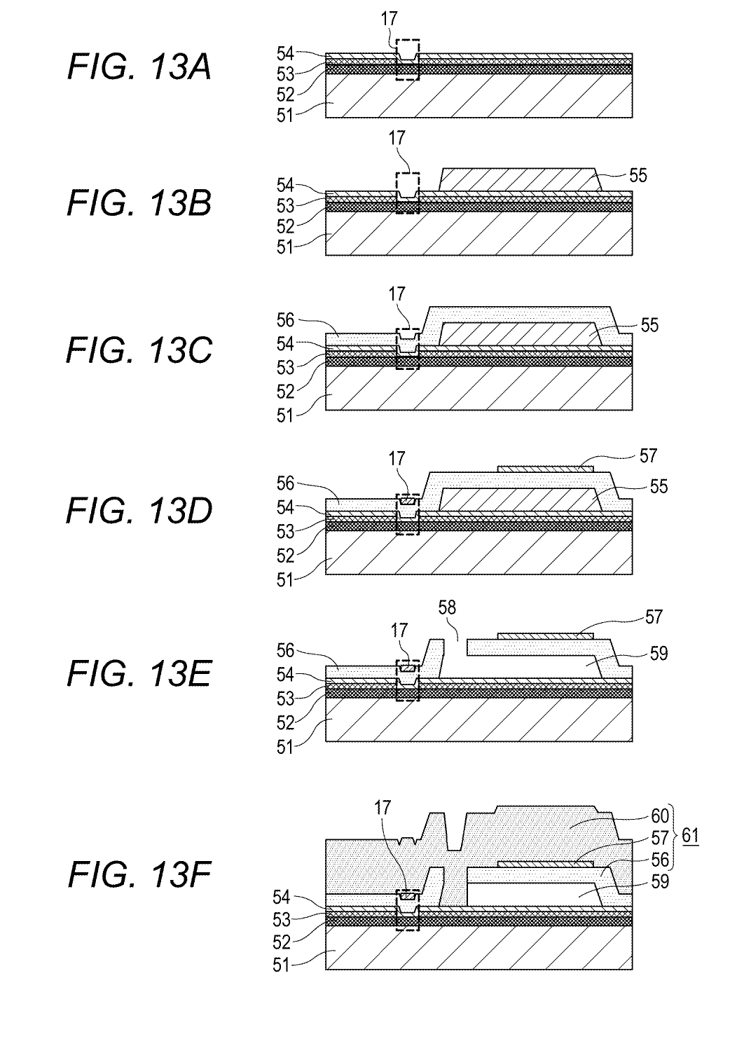

(1) A step of forming a first electrode 53 on a substrate 51 (FIG. 13A).

(2) A step of forming a plurality of sacrifice layer areas 55 on the first electrode 53 with an independent gap in each of cell structures (FIG. 13B). FIG. 13B illustrates only one cell structure and does not describe the other cell structures.

(3) A step of forming a second electrode 57 on the sacrifice layer area 55 (FIG. 13D).

(4) The sacrifice layer area 55 is removed to form an independent gap 59 in each of the cell structures (FIG. 13E).

The first electrode 53 is formed such that the first electrode 53 and the second electrode 57 oppose to each other only in an area with the gap 59 therebetween. Although there is no particular limitation on how to form the first electrode 53, the first electrode 53 may be formed by a step of forming the first electrode 53 on the entire substrate 51 and removing part of the formed first electrode 53 (the area 17 illustrated in FIG. 13). Alternatively, the first electrode 53 may be formed on the substrate 51 only at a necessary position.

The area of the second electrode provided on the sacrifice layer area may be smaller than the sacrifice layer area.

One example of a method for manufacturing the capacitive micromachined ultrasonic transducer 1 according to the embodiment will be described with reference to FIG. 13. FIG. 13 is a cross-sectional view of FIG. 1 taken along line E-F. As illustrated in FIG. 13A, a first insulation film 52 is formed on the substrate 51. The substrate 51 is a silicon substrate, and the first insulation film 52 is intended to provide insulation from the first electrode 53. When the substrate 51 is an insulating substrate such as a glass substrate, the first insulation film 52 may not be formed. The substrate 51 is desirably a substrate with small surface roughness. When the substrate 51 has large surface roughness, the surface roughness is transferred in the film forming step after this step, and the distance between the first electrode 53 and the second electrode 57 varies between the cells due to the roughness. The variations lead to conversion efficiency variations, sensitivity variations, and band variations. Therefore, the substrate 51 desirably has small surface roughness. Then, the first electrode 53 is formed on the substrate 51. The first electrode 53 is desirably made of a conductive material with small surface roughness, for example, such as titanium, tungsten, or aluminum. Like the substrate 51, when the first electrode 53 has large surface roughness, the distance between the first electrode 53 and the second electrode 57 varies between the cells and between the elements due to the surface roughness. Accordingly, the conductive material for the first electrode 53 has desirably small surface roughness. The first electrode 53 is desirably thin because the larger thickness increases the surface roughness. Of the first electrode 53 opposed to the second electrode 57 to be formed later, the portion in the area without the gap 59 to be formed later is removed at least in a size almost identical to the second electrode 57 to form the portion 17 from which the first electrode is removed. The almost identical size is preferably a size in which the second electrode 57 to be formed later does not overlap the first electrode 53 even if the second electrode 57 is deviated in alignment accuracy. The size is preferably decided allowing for the alignment accuracy of the exposure device and the patterning accuracy at the time of manufacture. In addition, the size preferably satisfies the desired parasitic capacity described later even if the second electrode 57 overlaps the first electrode 53. The alignment accuracy and patterning accuracy at the time of manufacture will be described. For example, when the accuracy of a device such as a stepper is estimated to be ±0.05 to 0.1 um and the accuracy of a device such as an aligner is to be ±0.5 to ±1 um, the size of the first electrode 53 is preferably made larger than the second electrode 57 by about 0.1 to 2 um. The first electrode 53 is preferably thin because, when part of the first electrode 53 is removed, the surface of the substrate has numerous differences in the level which may adversely affect the coverage of a film to be formed later.

Next, a second insulation film 54 is formed as illustrated in FIG. 13A. The second insulation film 54 is desirably made of an insulating material with small surface roughness and is formed to prevent electric short-circuit or dielectric breakdown between the first electrode 53 and the second electrode 57 when a voltage is applied between the first electrode 53 and the second electrode 57. In addition, the second insulation film 54 is formed to prevent the first electrode from being etched at the time of removal of the sacrifice layer in the step following the present step. Like the substrate, when the second insulation film 54 has large surface roughness, the distance between the first electrode and the second electrode varies among the cells due to the surface roughness. This is because the second insulation film 54 is desirably made of an insulation film with small surface roughness. For example, the insulation film is a silicon nitride film, a silicon oxide film, or the like. The insulation film has a minimum thickness necessary for providing insulation because the insulation film has larger surface roughness with the increased thickness. Moreover, the second insulation film 54 is formed on the first electrode 53 and thus desirably has a thickness enough to cover with reliability the step on the portion 17 from which the first electrode is removed.

Next, the sacrifice layer 55 is formed as illustrated in FIG. 13B. The sacrifice layer 55 is desirably made of a material with small surface roughness. Like the substrate 51, when the sacrifice layer 55 has large surface roughness, the distance between the first electrode 53 and the second electrode 57 varies among the cells due to the surface roughness. Thus, the sacrifice layer 55 desirably has small surface roughness. In addition, the sacrifice layer 55 is desirably made of a material with a high etching rate to shorten the etching time for removing the sacrifice layer 55. Further, the material for the sacrifice layer is virtually desired to keep the second insulation film 54 and a third insulation film 56 to be a vibrating membrane 61 from being etched by an etching solution or etching gas for removing the sacrifice layer 55. When the second insulation film 54 and the third insulation film 56 to be the vibrating membrane 61 are etched by the etching solution or etching gas for removing the sacrifice layer 55, the thickness of the vibrating membrane 61 varies and the distance between the first electrode 53 and the second electrode 57 also varies. The variations in the thickness of the vibrating membrane 61 and the variations in the distance between the first electrode 53 and the second electrode 57 lead to variations in the sensitivity and band among the cells. When the second insulation film 54 and the vibrating membrane 61 are silicon nitride films or silicon oxide films, the material for the sacrifice layer desirably allows the use of an etching solution or etching gas by which the second insulation film 54 and the vibrating membrane 61 are unlikely to be etched. For example, the material for the sacrifice layer is amorphous silicon, polyimide, chrome, or the like. In particular, when the second insulation film 54 and the vibrating membrane 61 are silicon nitride films or silicon oxide films, the etching solution of chrome is desired because it allows a silicon nitride film or a silicon oxide film to be hardly etched.

Next, the third insulation film 56 is formed as illustrated in FIG. 13C. The third insulation film 56 desirably has low tensile stress. For example, the third insulation film 56 has a tensile stress of 500 MPa or less. The silicon nitride film is capable of stress control and achieves a low tensile stress of 500 MPa or less. When the vibrating membrane 61 has compressive stress, the vibrating membrane 61 causes sticking or buckling and deforms significantly. In addition, with high tensile stress, the third insulation film 56 may become broken. This is because the third insulation film 56 desirably has low tensile stress. For example, the third insulation film 56 is a silicon nitride film that is capable of stress control and achieves low tensile stress. Moreover, the third insulation film 56 is formed on the sacrifice layer 55 and the step in the portion 17 from which the first electrode is removed. Therefore, the third insulation film 56 desirably has a thickness enough to cover with reliability the sacrifice layer 55 and the step in the portion 17 from which the first electrode is removed.

Next, the second electrode 57 is formed as illustrated in FIG. 13D. The second electrode 57 is desirably made of a material with low residual stress, for example, aluminum. When the sacrifice layer removal step or the sealing step is performed after the formation of the second electrode 57, the second electrode 57 is desirably made of a material with etching resistance and heat resistance to the sacrifice layer etching. For example, the material for the second electrode 57 is an aluminum-silicon alloy, titanium, or the like. At the formation of the second electrode 57, the second electrode 57 is preferably made in a size and with an alignment accuracy satisfying the desired parasitic capacity described later at the portion 17 from which the first electrode is removed. In addition, the second electrode 57 preferably has a thickness to cover the step on the surface with reliability.

Next, an etching hole 58 is formed in the third insulation film 56 as illustrated in FIG. 13E. Referring to FIG. 13E, an etching hole 58 is a hole through which an etching solution or etching gas is introduced to etch and remove the sacrifice layer 55. After that, the sacrifice layer 55 is removed to form the gap 59. The method for removing the sacrifice layer is preferably wet etching or dry etching. Wet etching is preferred when the material for the sacrifice layer is chrome. When the material for the sacrifice layer is chrome, the second electrode 57 is preferably made of titanium so that the second electrode 57 will not be etched at the time of etching of the sacrifice layer. When the second electrode 57 is made of an aluminum-silicon alloy or the like, it is preferred to, after the formation of the second electrode 57, form an insulation film from the same material as that for the third insulation film 56 on the second electrode 57, and then form the etching hole 58 to remove the sacrifice layer.

Next, a sealing film 60 is formed to seal the etching hole 58 as illustrated in FIG. 13F. The vibrating membrane 61 is formed by the third insulation film 56, the second electrode 57, and the sealing film 60. The sealing film 60 is required to block infiltration of a liquid or outside air into the gap 59. When the gap 59 is under atmospheric pressure, the gas in the gap 59 expands or contracts with temperature changes. In addition, the gap 59 is brought under a high electric field, which causes reduction in the reliability of the element due to the ionization of molecules or the like. Accordingly, the sealing is desirably performed in a reduced-pressure environment. Reducing the pressure in the gap 59 makes it possible to reduce the air resistance inside the gap 59. This makes the vibrating membrane 61 easier to vibrate, thereby enhancing the sensitivity of the capacitive micromachined ultrasonic transducer 1. The sealing also allows the use of the capacitive micromachined ultrasonic transducer 1 in a liquid. The same sealing material as that for the third insulation film 56 is preferably high in adhesiveness. In addition, the sealing film 60 preferably has a thickness to cover the step on the surface with reliability. When the third insulation film 56 is made of silicon nitride, the sealing film 60 is preferably made of silicon nitride as well.

FIG. 13A-13F illustrate an example of a configuration in which the second electrode 57 is sandwiched between the third insulation film 56 and the sealing film 60. Alternatively, after the formation of the third insulation film 56, the etching hole (opening) 58 may be formed to etch the sacrifice layer. Then, after the formation of the sealing film 60, the second electrode 57 may be provided. However, the second electrode 57 is exposed to the outmost surface, the element is highly likely to cause a short. Accordingly, the second electrode 57 is preferably provided on the insulation film. Alternatively, after the formation of the sealing film 60 as illustrated in FIG. 13F, the sealing film 60 may be partially etched and thinned. The sealing film 60 is intended to seal the etching hole 58 and needs to be changed in thickness according to the thickness of the gap 59. To increase the thickness of the gap 59 and decrease the thickness of the sealing film 60, it is preferred to form the sealing film 60 with a thickness capable of sealing the etching hole 58 and then etch the sealing film 60 including a portion to be the vibrating membrane 61.

Through the foregoing steps, the state illustrated in FIG. 13F can be achieved to fabricate the capacitive micromachined ultrasonic transducer as illustrated in FIG. 1. Using lead-out wiring, not illustrated, electrically connected to the second electrode pad 42 illustrated in FIG. 2 makes it possible to extract an electric signal from the second electrode 57. To receive an ultrasonic wave by the capacitive micromachined ultrasonic transducer 1, DC voltage is applied in advance to the first electrode 53. Upon receipt of an ultrasonic wave, the vibrating membrane 61 having the second electrode 57 deforms to alter the distance of the gap 59 between the second electrode 57 and the first electrode 53, thereby changing the electrostatic capacity. The change of electrostatic capacity flows an electric current to the lead-out wiring. This electric current is subjected to current-voltage conversion in the transmission-reception circuit 27 illustrated in FIG. 8 so that the ultrasonic wave can be received as a voltage. In addition, when the DC voltage is applied to the first electrode 53 and the transmission driving voltage is applied to the second electrode 57, the vibrating membrane 61 can be vibrated by electrostatic force. This allows transmission of the ultrasonic wave.

### Example 1

In relation to Example 1, the reception S/N of the capacitive micromachined ultrasonic transducer 1 will be discussed to describe the effect of aspects of the present disclosure.

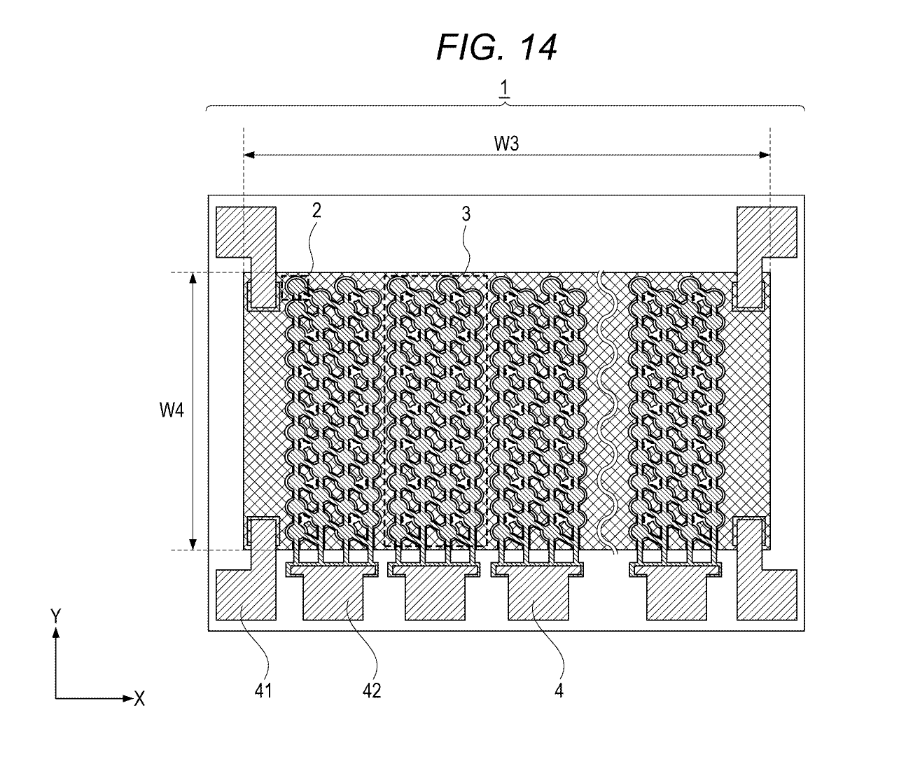

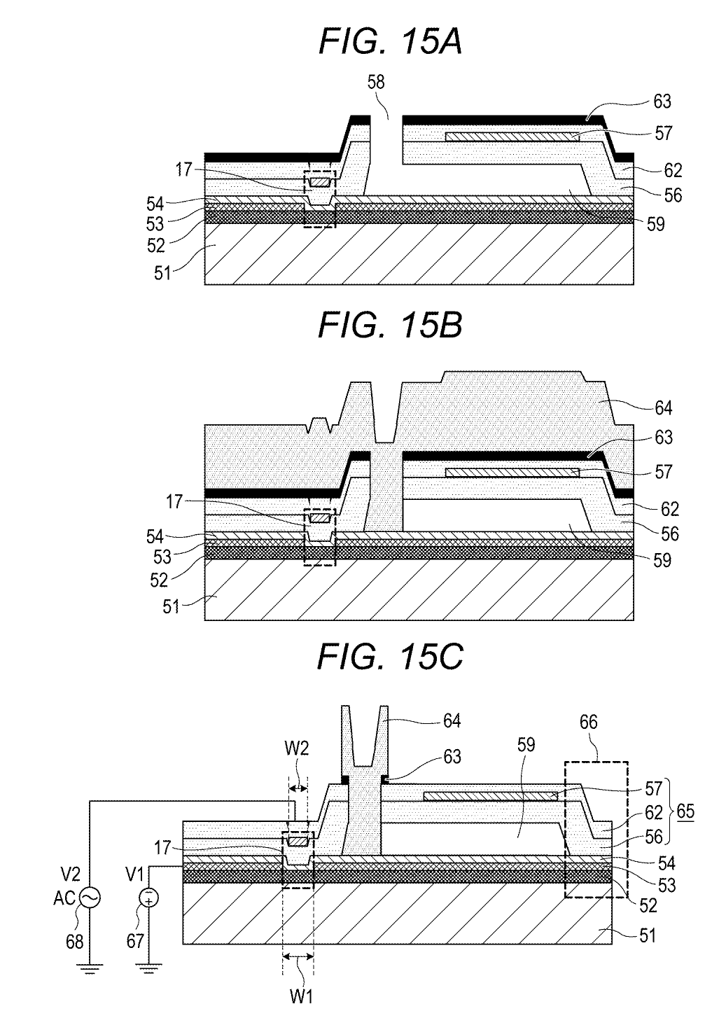

The capacitive micromachined ultrasonic transducer 1 according to Example 1 will be described with reference to FIGS. 14, 1, and 15A-15C. FIG. 14 is a top view of the capacitive micromachined ultrasonic transducer according to Example 1. The enlarged schematic diagram of FIG. 14 is in common with FIG. 1. FIGS. 15 A-15C are cross-sectional view of FIG. 1 taken along line E-F.

The outer dimensions of the capacitive micromachined ultrasonic transducer 1 illustrated in FIG. 14 are 12 mm along the Y axis by 45 mm along the X axis. The outer dimensions of the element 3 are 0.3 mm along the X axis by 4 mm along the Y axis. There are 196 elements 3 aligned in a one-dimensional array. FIG. 1 is a schematic enlarged view of a portion of FIG. 14, and FIG. 15C is a cross-sectional view of FIG. 1 taken along line E-F. The cells 2 constituting the elements 3 are circular in shape and the diameter of the gap 8 is 15 um. The cells 2 are most closely arranged as illustrated in FIG. 14. The adjacent cells 2 constituting one element 3 are arranged with space of 17 um therebetween. That is, the shortest distance of the gap 8 between the adjacent cells 2 is 2 um. Although FIG. 14 does not illustrate all the cells, 4690 cells are actually arranged in one element 3 in two mixed patterns where 20 cells are aligned in the X direction and 234 or 235 cells are aligned in the Y direction.

A section structure and a manufacturing method will be described with reference to FIGS. 15A-15C. As illustrated in FIG. 15C, each of the cells 2 has the silicon substrate 51 with a thickness of 300 um, the first insulation film 52 formed on the substrate 51, the first electrode 53 formed on the first insulation film 52, and the second insulation film 54 formed on the first electrode 53. Each of the cells 2 also has a vibrating membrane 65 including the second electrode 57, the third insulation film 56, and a fourth insulation film 62, and a vibrating membrane support member 66 supporting the vibrating membrane 65, and the gap 59. The gap 59 has a height of 300 nm. Each of the cells 2 further has a voltage applying unit 67 for applying the bias voltage between the first electrode and the second electrode and a voltage applying unit 68 for applying the transmission voltage to the second electrode.

The first insulation film 52 is a 1 um-thick silicon oxide film formed by thermal oxidation. The second insulation film 54 is a 400 um-thick silicon oxide film formed by plasma enhanced chemical vapor deposition (PE-CVD). The first electrode 53 is 50 nm thick and made of tungsten. A portion of the first electrode 53 opposed to the second electrode 57 in the area without the gap 59 is removed at least in a size almost identical to the second electrode 57. Referring to FIG. 15C, when line width W2 of the first electrode 53 is 5 um, width W1 of the portion from which the first electrode is removed is set to 6 um. The width W1 of the removed portion of the first electrode 53 is preferably suited to the alignment accuracy of the exposure device for use in manufacture and the patterning accuracy. In this case, the area of the removed portion of the first electrode 53 is ≈22 mm̂2. Meanwhile, the first electrode 53 has W3 of 41 mm along the X axis and W4 of 4 mm along the Y axis, and therefore the area of the first electrode is 164 mm̂2−22 mm̂2≈142 mm̂2. Setting the area of the first electrode 53 to be larger than the area of the removed portion of the first electrode 53 preferably reduces the resistance of the element pitch 40 in the first electrode 53.

The second electrode 57 is a 100 nm-thick Al—Nd alloy. The third insulation film 56 and the fourth insulation film 62 are silicon nitride films fabricated by PE-CVD under a tensile stress of 450 Mpa or less. The third insulation film 56 is 200 nm thick and the fourth insulation film 62 is 100 nm thick.

In Example 1, after the formation of the second electrode 57, the fourth insulation film 62 is formed as illustrated in FIG. 15A. In addition, a stopper layer 63 is formed on the fourth insulation film 62. The stopper layer 63 is 100 nm thick and made of Al. After the formation of the stopper layer 63, the etching hole 58 is formed and the sacrifice layer is removed to form the gap 59. The sacrifice layer is removed by dry etching with xenon fluoride using amorphous silicon. Next, a sealing film 64 is formed with a thickness of 900 nm as illustrated in FIG. 15B. The sealing film 64 is a silicon nitride film fabricated by PE-CVD. The sealing film 64 has a thickness of 900 nm to seal the gap 59. Next, the sealing film 64 is partially removed as illustrated in FIG. 15C. The sealing film 64 is removed by dry etching except for the portion sealing the gap 59. In this case, the stopper layer 63 serves as an etching stopper for the sealing film 64. After that, the stopper layer 63 is removed by wet etching to form the vibrating membrane 65 from the third insulation film 56, the second electrode 57, and the fourth insulation film 62. Having undergone the foregoing steps, the capacitive micromachined ultrasonic transducer 1 has the first electrode 53 connectable at the first electrode pads 41 at four corners to the voltage applying unit 67. The second electrode 57 has wires led out by the second electrode pad 42 in each of the elements 3 so as to be connectable to the transmission-reception circuit 27 illustrated in FIG. 8. Having undergone the foregoing steps, the capacitive micromachined ultrasonic transducer as illustrated in FIG. 14 can be fabricated.

The capacitive micromachined ultrasonic transducer 1 is mounted on the circuit substrate 34 as illustrated in FIG. 9, the first electrode 53 is connected to the voltage applying unit 67, and the second electrode 57 is connected to the transmission-reception circuit. The acoustic lens 33 is mounted via the acoustic matching layer 32 on the vibrating membrane 65 of the capacitive micromachined ultrasonic transducer 1. The acoustic matching layer 32 is made of a silicon resin with a thickness of 30 um, and the acoustic lens 33 is made of a silicon resin with a curvature radius of 13 mm and a maximum thickness of 600 um. According to these steps, the ultrasonic probe 31 as illustrated in FIG. 9 can be produced.

The characteristics of the ultrasonic probe 31 having undergone the foregoing steps will be described. The capacitive micromachined ultrasonic transducer 1 has a pull-in voltage of 240 V. The pull-in voltage refers to a voltage under which the electrostatic attractive force is greater than the restoration force of the vibrating membrane when the voltage is applied between a pair of electrodes formed with a gap therebetween. When a voltage equal to or higher than pull-in voltage is applied, the vibrating membrane contacts the second insulation film on the bottom of the gap. When the vibrating membrane contacts the second insulation film, the frequency characteristics of the element varies significantly to change significantly the receiving sensitivity of the acoustic wave and the strength of the transmission sound pressure. When the elements constituting the ultrasonic probe include a mixture of elements to which the pull-in voltage or higher voltage is applied and elements to which such voltage is not applied, the receiving sensitivity and the transmission sound pressure vary more significantly. Therefore, in generality, the capacitive micromachined ultrasonic transducer 1 is preferably driven in the state the pull-in voltage or higher voltage is not applied. The capacitive micromachined ultrasonic transducer 1 is preferably driven with the bias voltage equal to or lower than the pull-in voltage, taking into account manufacture variations of the elements and fluctuations in bias voltage. In the embodiment, the bias voltage is set to 192 V which is 80% of the pull-in voltage, and the active capacity of the element 3 is 17 pF in this case. The parasitic capacity inside the capacitive micromachined ultrasonic transducer 1 is almost zero pf because the portion of the first electrode 53 overlapping the second electrode 57 without the gap 59 is removed. The parasitic capacity becomes 7 pF when the portion of the first electrode 53 overlapping the second electrode 57 without the gap 59 is not removed. In addition, the parasitic capacity occurs due to connection to the transmission-reception circuit 27 or routing of wires in the substrate of the transmission-reception circuit 27.

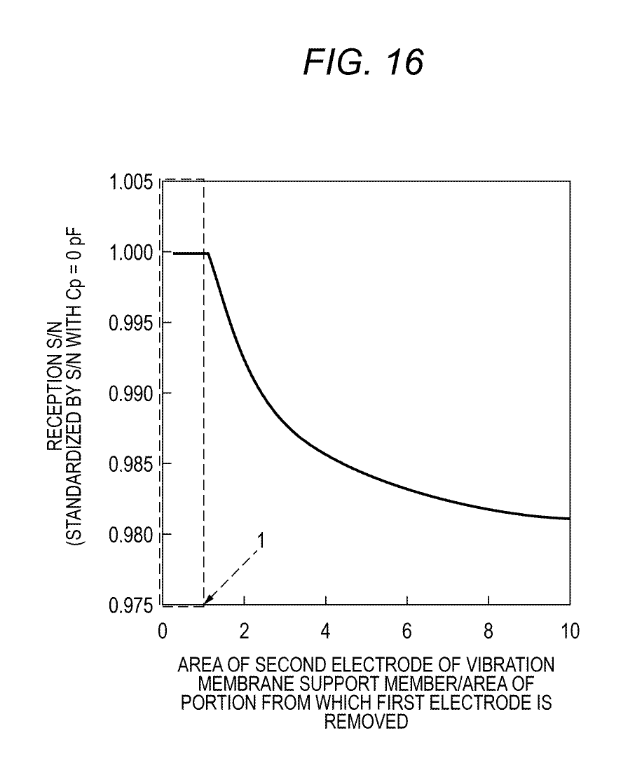

FIG. 16 illustrates changes in S/N depending on the area of the portion 17 from which the first electrode is removed. The axis of abscissae in FIG. 16 indicates the area ratio of the second electrode 57 of the vibrating membrane support member 14 and the portion 17 from which the first electrode is removed, and the axis of ordinates in FIG. 16 indicates the value obtained by dividing the reception S/N on the axis of abscissae by the reception S/N with the parasitic capacity Cp=0 pF. As illustrated in FIG. 16, when the area of the portion 17 from which the first electrode is removed increases with respect to the area of the second electrode 57 of the vibrating membrane support member 14, the parasitic capacity inside the capacitive micromachined ultrasonic transducer 1 decreases and the reception S/N improves. When the area of the portion 17 from which the first electrode is removed becomes equal to or larger than the area of the second electrode 57 of the vibrating membrane support member 14, the parasitic capacity inside the capacitive micromachined ultrasonic transducer 1 remains unchanged and the reception S/N takes a constant value. From this matter, the first electrode 53 is preferably removed in a size equal to at least the second electrode 57 of the vibrating membrane support member 14. Area ratio X between the second electrode 57 of the vibrating membrane support member 14 and the portion 17 from the first electrode is removed preferably falls within a range of X≤1 which is surrounded by broken lines in FIG. 16. When X is smaller, the portions 17 from which the first electrode is removed overlap, and the first electrode 53 cannot serve as a common electrode in the capacitive micromachined ultrasonic transducer 1. This is because the area ratio preferably falls within the functional range.

It is necessary to form the first electrode 53 allowing for the alignment accuracy of the exposure device and the patterning accuracy. The width W1 of the portion 17 from which the first electrode 53 is removed is preferably larger than the width W1 of the vibrating membrane support member 14 of the second electrode 57 by about 0.1 to 2 um. In addition, the length of the portion 17 from which the first electrode 53 is removed is 2 um which is equal to the shortest distance of the gap 8 between the adjacent cells 2. From this matter, the width W1 of the first electrode 53 is preferably 5.1 um or more at minimum and may be 7.0 um or more. The length of the first electrode 53 is preferably 2.1 um or more at minimum and may be 4.0 um or more. The foregoing almost identical size refers to a size allowing for the alignment accuracy of the exposure device and the patterning accuracy. In the embodiment, the foregoing values are regarded as almost identical sizes.

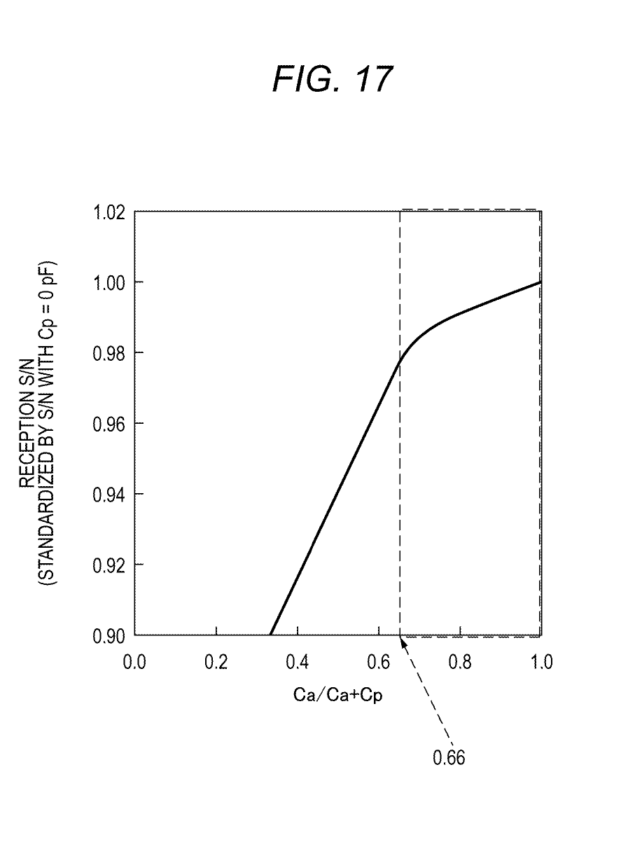

FIG. 17 illustrates changes in S/N with Ca/Ca+Cp as expressed in Equation 1. The axis of abscissae in FIG. 17 indicates the ratio Ca/Ca+Cp of the active capacity+the parasitic capacity to the active capacity, and the axis of ordinates in FIG. 17 indicates the value obtained by dividing the reception S/N with Ca/Ca+Cp by the reception S/N with the parasitic capacity Cp=0 pF. When Cp increases, Cin increases accordingly. Therefore, the cutoff frequency in the circuit of the reception unit 29 is set to be uniform, the minimum value of Cf satisfying Equation 4 is selected, the value of Rf with maximum circuit gain of the reception unit 29 is selected, and the reception characteristics and the cumulative noise of the detection circuit are calculated. The reception unit 29 is a transimpedance-type current-voltage amplifier circuit, and the cutoff frequency is 5 MHz.

As illustrated in FIG. 17, when Ca/Ca+Cp becomes smaller, the reception S/N decreases. The S/N with Ca/Ca+Cp=1 is 1 in the structure of Example 1, whereas the S/N with no removal of the portion of the first electrode 53 overlapping the second electrode 57 without the gap 59 (Ca/Ca+Cp=0.62) is 0.97. In addition, it can be seen from FIG. 17 that, with Ca/Ca+Cp=0.66 or more, the reception S/N changes moderately. Accordingly, the structure preferably satisfies Ca/Ca+Cp≥0.66. FIG. 17 illustrates the preferable range surrounded by broken lines. The minimum width W2 of the first electrode 53 necessary for satisfying Ca/Ca+Cp≥0.66 in the structure of Example 1 will be described. The parasitic capacity satisfying Ca/Ca+Cp≥0.66 in the structure of Example 1 is 8.8 pF. Based on the premise that the parasitic capacity is 7 pF in the transmission-reception circuit, the parasitic capacity in the capacitive micromachined ultrasonic transducer 1 needs to be 1.8 pF or less. The width W1 of the second electrode 57 exists in four places of one cell. The second electrode 57 has a length of 2 um and the width W1 of 5 um. When the relative permittivity of the second insulation film 54 is 4.45 and the relative permittivity of the third insulation film 56 is 6.8, and the vacuum permittivity is 8.854×10̂−12 F/m, the width W2 can be roughly determined as follows:

W2=(5×10̂−6 (m))−(1.8×10̂−12 F/(4690(units)×4(portions)/2)×(400×10̂−9 (m)/4.45+200×10̂−9 (m)/6.8)/(8.854×10̂−12(F/m)×1×10̂−6 (m)×4(portions))/4≈4.8 (um)

Setting the width W1 of the first electrode 53 to 4.8 um or more satisfies Ca/Ca+Cp≈0.66. Allowing for the alignment accuracy of the exposure device and the patterning accuracy, the width W1 of the first electrode 53 is preferably larger than the width W1 of the second electrode 57 by about 0.1 to 2 um. Accordingly, the width W1 of the first electrode 53 is preferably 4.9 um or more at minimum and may be 6.8 um or more. The length of the first electrode 53 is preferably identical to the length in FIG. 16 described above.

However, when the width W1 and length of the first electrode 53 illustrated in FIGS. 16 and 17 are made large beyond necessity, the portions 17 from which the first electrode is removed overlap, and the first electrode 53 cannot serve as a common electrode in the capacitive micromachined ultrasonic transducer 1. This is because the width W1 and length of the first electrode 53 preferably fall within the functional ranges in which the first electrode 53 can function as a common electrode in the capacitive micromachined ultrasonic transducer 1. In the example, the width W1 of the first electrode 53 is preferably 4.9 to 7.0 um, and the length of the first electrode 53 is preferably 2.1 to 4.0 um.

The width W1 and length of the first electrode 53 are preferably set allowing for the alignment accuracy of the device for use in manufacture and the patterning accuracy. In addition, the width W1 and length of the first electrode 53 are preferably set to obtain the parasitic capacity with desired characteristics.

Accordingly, employing the configuration of Example 1 makes it possible to improve the reception characteristics.

### Example 2

In Example 2, the transmission characteristics of the capacitive micromachined ultrasonic transducer 1 will be discussed to explain the advantageous effect of aspects of the present disclosure. Changes in electric crosstalk due to the resistance of the element pitch 40 in the 53 will be described.

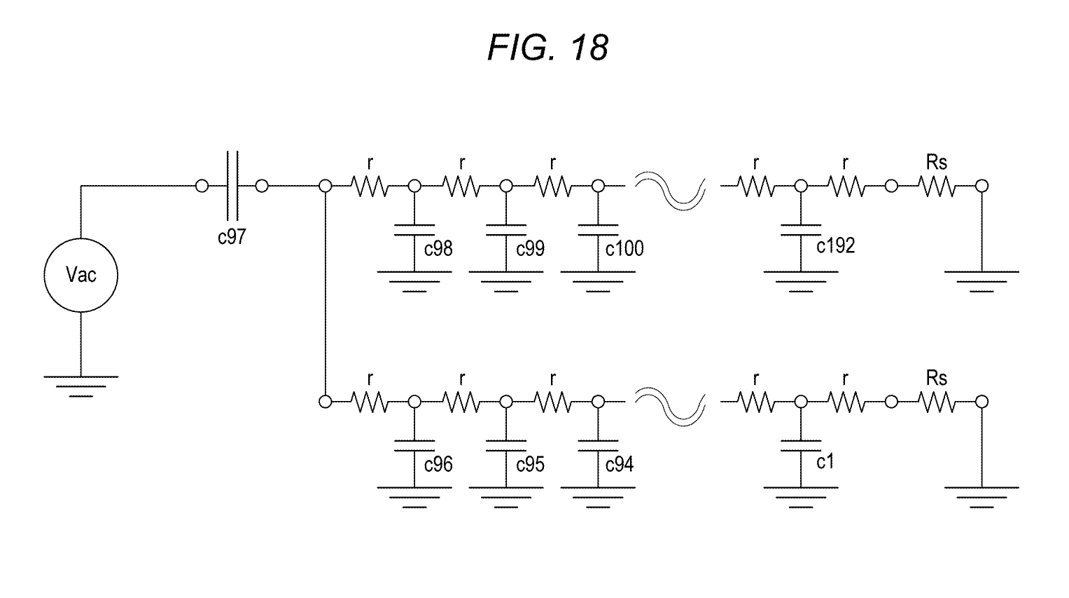

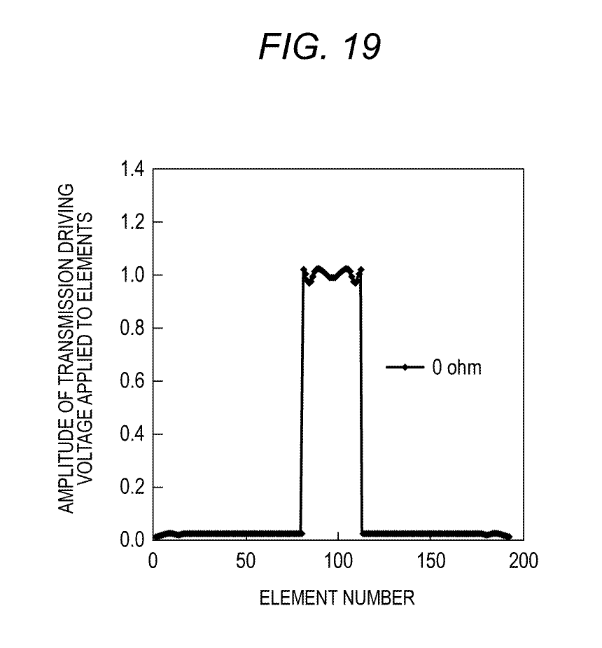

FIG. 18 is a diagram of a transmission circuit for transmission from the ultrasonic probe 31 in Example 1. FIGS. 19, 20, and 21 illustrate the relationship between the resistance of the element pitch 40 in the first electrode 6 and the amplitude of the transmission driving voltage applied to the elements 3 due to electric crosstalk. Referring to FIG. 18, 192 elements 3 are provided, the first electrode 53 is connected in common to all the elements 3, transmission driving voltage Vac is applied to the 97th element. The capacities of the 192 elements 3 are designated as c1 to c192, the resistance of the element pitch 40 in the first electrode 6 as r, and the resistance between the first electrode 53 and the ground as Rs. The resistance Rs is set to 5Ω. The capacities of the elements 3 are set to 20 pF including the active capacity and the parasitic capacity. Descriptions will be given as to the case where the transmission circuit as illustrated in FIG. 18 performs beam forming transmission driving using the 32 elements from the 81st element 3 to the 112th element 3. In Example 2, the beam forming transmission driving is performed using the 32 elements such that the sound pressure becomes maximum at a position 21 mm propagated from the surface of the ultrasonic probe 31. For that end, the transmission driving is performed at different time points for applying the transmission driving voltage, from the 81st element and the 112th element at the end to the 96th element and the 97th element in the center.

Referring to FIG. 18, when the transmission driving voltage Vac is applied to the 97th element with an amplitude of 1, the bias voltage fluctuates due to the resistance r between the other elements 3 and the capacities c1 to c192. Accordingly, the potential difference changes between the first electrode 53 and the second electrode 57 in the other elements 3. This is electric crosstalk. When the beam forming driving is performed, the transmission driving voltage Vac is applied with an amplitude of 1 to the other elements 3 in sequence, thereby causing electric crosstalk in succession. The electric crosstalk is superimposed on the transmission driving voltage Vac applied to the elements 3 for the beam forming driving. Since the vibrating membrane 65 vibrates under the superimposed transmission driving voltage, the transmission characteristics change depending on the electric crosstalk.

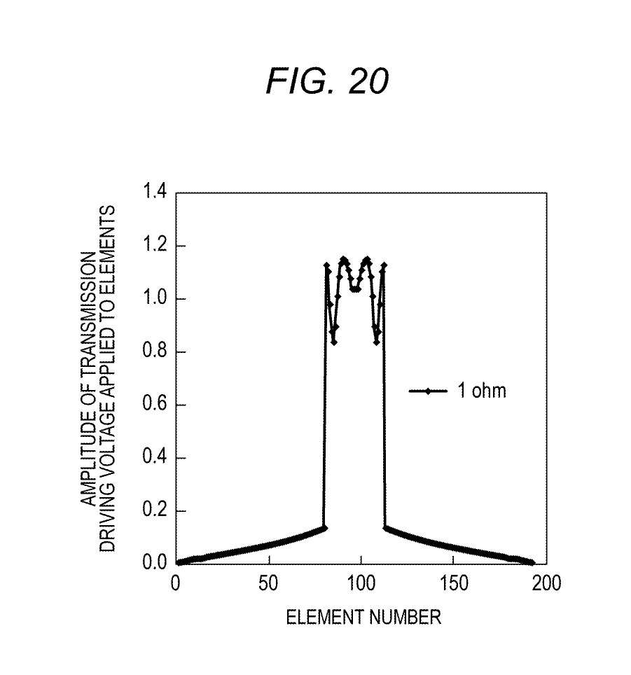

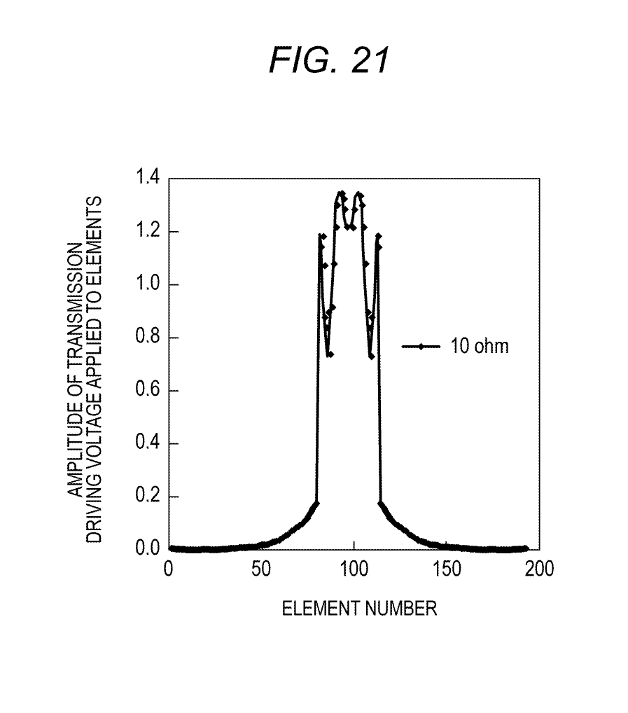

In FIGS. 19, 20, and 21, the axis of ordinates indicates the amplitude of the transmission driving voltage on which the electric crosstalk is superimposed, and the axis of abscissae indicates the element number. The applied transmission driving voltage Vac in these graphs is 8 MHz. FIG. 19 illustrates the case where the element pitch resistance 40 in the first electrode 53 is 0Ω. In this case, the amplitude of the transmission driving voltage on which the electric crosstalk in superimposed varies in a range of +2.7 to −2.9%. FIG. 20 illustrates the case where the element pitch resistance 40 in the first electrode 53 is 1Ω. In this case, the amplitude of the transmission driving voltage on which the electric crosstalk in superimposed varies in a range of +15.2 to −16.1%. FIG. 21 illustrates the case where the element pitch resistance 40 in the first electrode 53 is 10Ω. In this case, the amplitude of the transmission driving voltage on which the electric crosstalk in superimposed varies in a range of +34.5 to −26.3%.

Since the transmission sound pressure becomes higher as the transmission driving voltage is raised to increase the vibration of the vibrating membrane. Accordingly, the driving is preferably under as high transmission driving voltage as possible. In addition, the sum of the bias voltage and the transmission driving voltage is preferably equal to or lower than the pull-in voltage. When the sum of the bias voltage and the transmission driving voltage is equal to or higher than the pull-in voltage, the vibrating membrane 65 contacts the second insulation film 54 on the bottom of the gap 59. When the vibrating membrane 65 contacts the second insulation film 54, the strength of the transmission sound pressure varies significantly. When the elements 3 constituting the ultrasonic probe 31 include a mixture of elements 3 to which the pull-in voltage or higher voltage is applied and elements 3 to which such voltage is not applied, the transmission sound pressure vary more significantly. Therefore, in generality, the elements 3 are preferably driven in the state the pull-in voltage or higher voltage is not applied. From the foregoing matter, it is necessary to perform the transmission driving such that the vibrating membranes 65 of all the elements 3 do not contact the second insulation film 54 allowing for the variations in the amplitude of the transmission driving voltage on which the electric crosstalk is superimposed.

In relation to Example 2, descriptions will be given as to the transmission driving in which the bias voltage is 50% of the pull-in voltage. When the resistance of the element pitch 40 in the first electrode 53 is 0Ω, the amplitude of the transmission driving voltage needs to be lower than 47.3% of the pull-in voltage. When the resistance of the element pitch 40 in the first electrode 53 is 1Ω, the amplitude of the transmission driving voltage needs to be lower than 34.8% of the pull-in voltage. When the resistance of the element pitch 40 in the first electrode 53 is 10Ω, the amplitude of the transmission driving voltage needs to be lower than 15.5% of the pull-in voltage. When the resistance of the element pitch 40 in the first electrode 53 becomes larger, the amplitude of the transmission driving voltage on which the electric crosstalk is superimposed varies more significantly. This requires decreasing the amplitude of the applicable transmission driving voltage, thereby leading to reduction in the obtained transmission sound pressure.

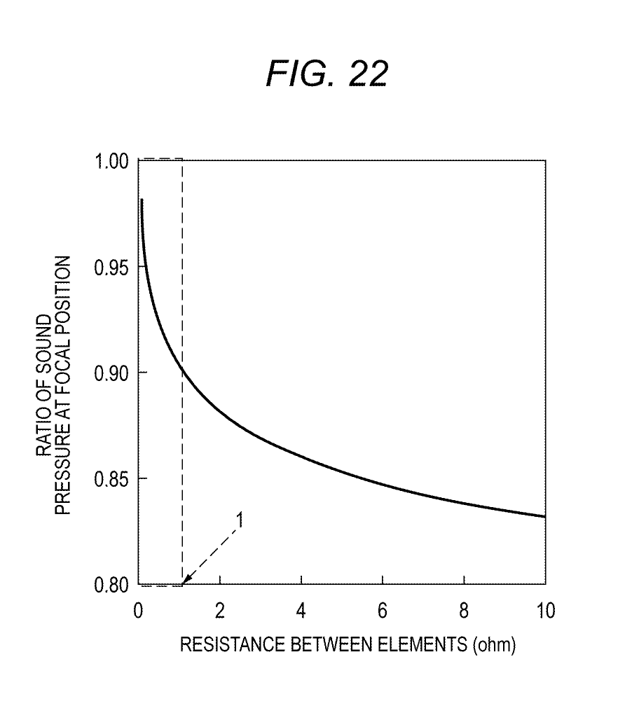

FIG. 22 illustrates the ratio between the resistance of the element pitch 40 in the first electrode 53 and sound pressure at 8 MHz at the focal position where beam forming driving is performed by 32 elements. The axis of abscissae in FIG. 22 indicates the resistance of the element pitch 40 in the first electrode 53, and the axis of ordinates in FIG. 22 indicates the sound pressure standardized when the resistance of the element pitch 40 in the first electrode 53 is 0Ω. As illustrated in FIG. 22, the obtained sound pressure becomes lower with the increasing resistance of the element pitch 40 in the first electrode 53. In general, a reduction of 10% of the sound pressure ratio remarkably affects the image. Since it can be seen from FIG. 22 that the sound pressure ratio drops 10% when the resistance of the element pitch 40 in the first electrode 53 is 1Ω, the resistance of the element pitch 40 in the first electrode 53 is preferably set to 1Ω or less. FIG. 22 illustrates the preferable range surrounded by broken lines.

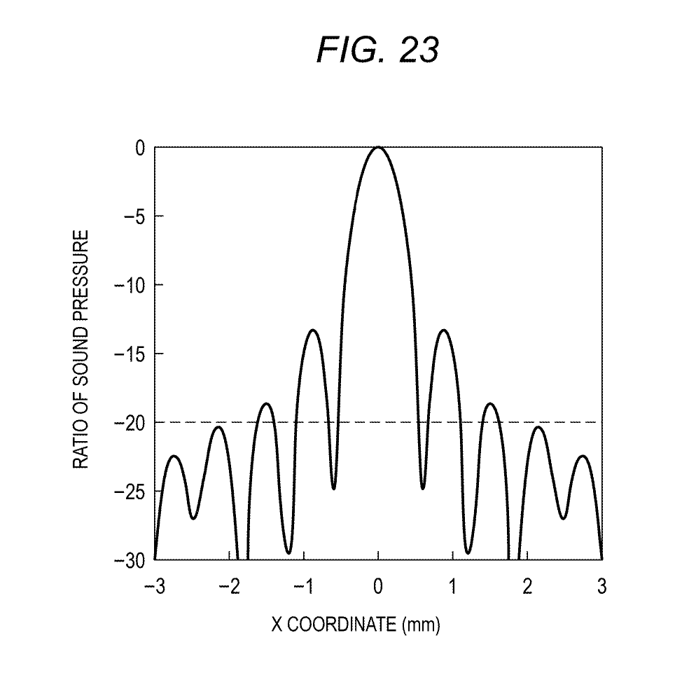

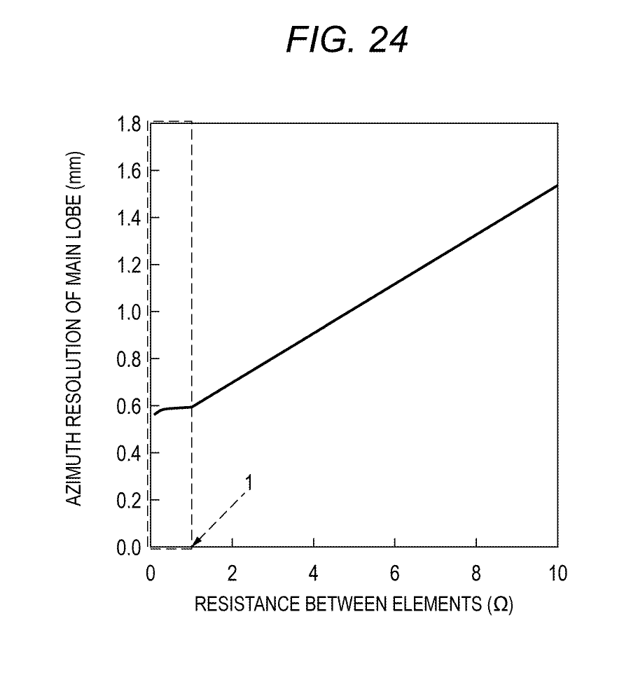

FIG. 23 illustrates the distribution of sound pressure at 8 MHz at the focal position where beam forming driving is performed by 32 elements when the resistance of the element pitch 40 in the first electrode 53 is 0Ω. The axis of abscissae in FIG. 23 indicates the distance along the X axis in FIG. 14, and the axis of ordinates in FIG. 23 indicates the sound pressure ratio standardized by the maximum sound pressure. It can be seen from FIG. 23 that the main lobe is around X=0 mm and the side lobes occur with increasing distance from the main lobe in the X direction. Referring to FIG. 23, the azimuth resolution of the main lobe at −20 dB is 0.56 mm. It can be said that the transmission characteristics is more favorable with the lower azimuth resolution. FIG. 24 illustrates the resistance of the element pitch 40 in the first electrode 53 and the azimuth resolution at 8 MHz at the focal position where beam forming driving is performed by 32 elements. The axis of abscissae in FIG. 24 indicates the resistance of the element pitch 40 in the first electrode 53, and the axis of ordinates in FIG. 24 indicates the azimuth resolution at −20 dB with each resistance. It can be seen from FIG. 24 that the azimuth resolution decreases significantly when the resistance of the element pitch 40 in the first electrode 53 exceeds 1Ω. Accordingly, the resistance of the element pitch 40 in the first electrode 53 is preferably set to be 1Ω or less. FIG. 24 illustrates the preferable range surrounded by broken lines.

In the same structure as Example 1, the resistance of the element pitch 40 in the first electrode 53 is as described below. The resistivity of tungsten in the first electrode 53 is set to 5.3×10̂−8Ω·m, and the width 43 of one stage of the first electrode is set to 15 um. In this case, the resistance of the element pitch 40 can be roughly determined as follows:

Resistance of the element pitch 40=1/(1/(3×10̂−3 (m)×5.3×10̂−8(Ω·m)/(50×10̂−9 (m)×15×10̂−6 (m)))×234(steps))≈0.1(Ω)

In the structure of Example 2, the sound pressure ratio is 0.97, which is sufficient to acquire an image, and the azimuth resolution is also as preferably low as 0.57 mm.

In such a manner as described above, it is possible to produce a capacitive micromachined ultrasonic transducer for use in an acoustic wave conversion element or the like by removing the first electrode opposed to the second electrode in an area with no gap in at least a size almost identical to the second electrode. This configuration of the capacitive micromachined ultrasonic transducer reduces the parasitic capacity and the wiring resistance and improves the reception characteristics and the transmission characteristics.

According to the capacitive micromachined ultrasonic transducer of the present disclosure, the electrodes are opposed to each other only in an area with a gap therebetween to reduce the parasitic capacity. In addition, setting the area of the elements with the lower electrodes in the capacitive micromachined ultrasonic transducer to be wider than the area without the lower electrode increases the area of the electrodes and reduces the wiring resistance. Decreasing the parasitic capacity and reducing the wiring resistance enhances the characteristics of reception and transmission of ultrasonic waves.

While exemplary embodiments have been described, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-022466, filed Feb. 9, 2017, which is hereby incorporated by reference herein in its entirety.

What is claimed is:

1. A capacitive micromachined ultrasonic transducer comprising an element, wherein
the element includes a plurality of cells,
each of the cells include:
a substrate;
a first electrode provided on the substrate; and
a vibrating membrane that has a second electrode opposed to the first electrode with a gap between the first and second electrodes, wherein
the first electrodes in the plurality of cells are electrically connected together to form a first common electrode and the second electrodes in the plurality of cells are electrically connected together to form a second common electrode,
the first common electrode and the second common electrode are opposed to each other only in an area with the gap therebetween, and
an area of the element with the first common electrode is wider than an area of the element without the first common electrode.

2. The capacitive micromachined ultrasonic transducer according to claim 1, wherein an area of the second common electrode not opposed to the first common electrode is provided at least on the vibrating membrane support member.

3. The capacitive micromachined ultrasonic transducer according to claim 1, wherein resistance of the first common electrode is 1Ω or less.

4. The capacitive micromachined ultrasonic transducer according to claim 1, wherein resistance of the second common electrode is 1Ω or less.

5. The capacitive micromachined ultrasonic transducer according to claim 1, comprising a first insulation film between the substrate and the first electrode.

6. The capacitive micromachined ultrasonic transducer according to claim 1, comprising a second insulation film between the first electrode and the gap.

7. The capacitive micromachined ultrasonic transducer according to claim 1, comprising a third insulation film between the gap and the second electrode.

8. The capacitive micromachined ultrasonic transducer according to claim 1, comprising a fourth insulation film on the second electrode.

9. The capacitive micromachined ultrasonic transducer according to claim 1, comprising a fifth insulation film on the fourth insulation film.

10. The capacitive micromachined ultrasonic transducer according to claim 1, comprising a plurality of the elements, wherein the elements are configured to perform independently at least one of reception and transmission of ultrasonic waves.

11. A method for manufacturing a capacitive micromachined ultrasonic transducer including an element with a plurality of cell structures, comprising:
forming a first electrode on a substrate;
forming a plurality of sacrifice layer areas on the first electrode such that the individual cell structures have independent gaps;
forming a second electrode on the sacrifice layer areas; and
removing the sacrifice layer areas and forming the independent gaps in the individual cell structures,
wherein the first electrode is formed such that the first electrode and the second electrode are opposed to each other only in an area with the gap therebetween.

12. The method for manufacturing a capacitive micromachined ultrasonic transducer according to claim 11, further comprising:
forming the first electrode on the overall substrate; and
removing part of the formed first electrode to form a structure in which the first electrode and the second electrode are opposed to each other only in an area with the gap therebetween.

13. The method for manufacturing a capacitive micromachined ultrasonic transducer according to claim 11, wherein an area of the second electrode provided on the sacrifice layer areas is smaller than the sacrifice layer areas.
